(19) United States
(12) Patent Application Publication
(10) Pub. No.: US 2026/0090125 A1
(43) Pub. Date: Mar. 26, 2026

(54) OPTICAL SENSOR PACKAGE WITH A SUBSTRATE

(71) Applicant: SEMICONDUCTOR COMPONENTS INDUSTRIES, LLC, Scottsdale, AZ (US)

(72) Inventors: Swarnal BORTHAKUR, Boise, ID (US); Christopher D. SILSBY, Corvallis, OR (US)

(73) Assignee: SEMICONDUCTOR COMPONENTS INDUSTRIES, LLC, Scottsdale, AZ (US)

(21) Appl. No.: 18/893,520

(22) Filed: Sep. 23, 2024

(51) Int. Cl. H01L 27/146

(52) U.S. Cl. CPC H10F 39/811; H10F 39/026

(57) ABSTRACT

A package includes an inorganic substrate, and an optical sensor die disposed on a first portion of a top surface of the inorganic substrate. The package further includes a first inter-metal dielectric layer disposed on a second portion of the top surface and a second inter-metal dielectric layer disposed on a bottom surface of the inorganic substrate. At least one through-substrate via filled or lined with a conductive material electrically connects the first inter-metal dielectric layer and the second inter-metal dielectric layer.

### TECHNICAL FIELD

This description relates to packaging of semiconductor optical sensors.

### BACKGROUND

A semiconductor optical sensor is configured to convert a radiation intensity and a wavelength spectrum into electrical signals. The semiconductor optical sensor can be mounted on a ceramic substrate and packaged, for example, as a CLCC (Ceramic Leadless Chip Carrier) package. Smaller form factor optical sensors, which are in demand for mobile phone, cameras and automotive applications, can, for example, use Imaging Ball Grid Array (iBGA) packaging. The iBGA packages use organic or plastic substrates (e.g., a bismaleimide triazine (BT) substrate) instead of the ceramic substrate used, for example, in a CLCC package. Large format industrial sensor packages predominantly use CPGA (ceramic pin grid array) packaging, which are high-cost packages. Similarly, ceramic BGA packages are also higher cost than plastic BGA packages. A lower cost large format sensor would be desirable for many applications including, for example, automotive applications.

### SUMMARY

In an aspect, a package includes an inorganic substrate. An optical sensor die disposed on a first portion of a top surface of the inorganic substrate. A first inter-metal dielectric layer is disposed on a second portion of the top surface and a second inter-metal dielectric layer is disposed on a bottom surface of the inorganic substrate. At least one through-substrate via includes conductive material to electrically connect the first inter-metal dielectric layer and the second inter-metal dielectric layer.

In an aspect, a substrate includes a piece of glass. A die attach pad is disposed on a top surface of the piece of glass and configured to receive a semiconductor device die. Further, a first inter-metal dielectric layer is disposed adjacent to the die attach pad on the top surface, and a second inter-metal dielectric layer is disposed on a bottom surface of the piece of glass. At least one through-glass via extends from the top surface of the piece of glass to the bottom surface of the piece of glass.

Further, the first inter-metal dielectric layer includes conductive traces and pads configured to be wire bonded to the semiconductor device die received on the die attach pad, and the second inter-metal dielectric layer includes at least one conductive pad configured to receive a solder ball making an external contact to the semiconductor device die received on the die attach pad.

In an aspect, a method includes disposing at least one inorganic substrate on a carrier, the at least one inorganic substrate including at least one through-substrate via extending from a first side to an opposite second side. The at least one inorganic substrate may be a silicate-based substrate.

The method further includes forming wire bonds between an optical sensor die and traces and pads in a first inter-metal dielectric layer disposed on a first side of the at least one silicate-based substrate and placing a cover over the optical sensor die.

The method further includes applying encapsulating material on vertical sides of the cover, the optical sensor die, and the at least one inorganic substrate. The encapsulating material joins several individual inorganic substrate substrates disposed on the carrier together.

The method further includes singulating through the encapsulating material to isolate individual inorganic substrates on the carrier, transferring the individual inorganic substrates in upside down position onto a die holder, and disposing solder bumps on a second inter-metal dielectric layer on the opposite second side of the individual inorganic substrates.

The details of one or more implementations are set forth in the accompanying drawings and the description below. Other features will be apparent from the description and drawings, and from the claims.

### BRIEF DESCRIPTION OF THE DRAWINGS

FIGS. 1A, 1B, and 1C illustrate example optical sensor packages in which an optical sensor die is disposed on a glass substrate, in accordance with the principles of the present disclosure.

FIGS. 2A, 2B, 2C and 2D illustrate example optical sensor packages in which a cover placed above an optical sensor die is as wide or almost as wide as a glass substrate on which the optical sensor die is disposed, in accordance with the principles of the present disclosure.

FIG. 3 illustrates a cross-sectional view of an optical sensor package in which a cover is disposed above an optical sensor die and forms an air cavity having a vent above the die.

FIG. 4 illustrates a cross-sectional view of another optical sensor package in which a cover is disposed above an optical sensor die and forms an air cavity having a vent above the die.

FIG. 5 is an exploded cross-sectional view of an optical sensor package illustrating package features designed to reduce flare.

FIG. 6 illustrates an example method for fabricating an optical sensor package.

FIGS. 7A through 7I illustrate cross-sectional views of a glass substrate being processed through multiple steps for making an optical sensor package, according to the method of FIG. 6.

FIG. 8 illustrates an example method for fabricating an optical sensor package.

FIGS. 9A through 9L illustrate cross-sectional views of a glass substrate being processed through multiple steps for making an optical sensor package, according to the method of FIG. 8.

In the drawings, which are not necessarily drawn to scale, like reference symbols or alpha numerals may indicate like and/or similar components in different views. The drawings illustrate generally, by way of example, but not by way of limitation, various implementations discussed in the present disclosure. Reference symbols shown in one drawing may not be repeated for the same, and/or similar elements in related views. Reference symbols or alpha-numeral identifiers that are repeated in multiple drawings may not be specifically discussed with respect to each of those drawings but are provided for context between related views. Also, not all like elements in the drawings are specifically referenced with a reference symbol or alpha-numeral identifier when multiple instances of an element are illustrated.

### DETAILED DESCRIPTION

An optical sensor (e.g., a digital optical sensor) fabricated on a semiconductor device die can include an optically active surface area (OASA) including an x-y array of pixel sensors responsible for converting a light and color spectrum into electrical signals. In some implementations, the optical sensor can be, for example, a complementary metal-oxide semiconductor (CMOS) pixel sensor. In some implementations, each pixel sensor in the array of pixel sensors may, for example, include a photo diode or a photo transistor that senses and converts incident light into an electrical signal. The OASA of an optical sensor may also include a color filter array (CFA). A CFA may be a mosaic of tiny color filters coupled to the pixel sensors to capture color information. For example, a Bayer RBG color filter or mosaic may include a pattern of red (R), blue (B) and green (G) color filters to capture color information related to the R, B and G colors. The OASA of an optical sensor may also include a microlens array to help funnel incoming light into each pixel to increase the sensitivity of the optical sensor. In some implementations, the microlens array can be an x-y array of microlenses.

A pixel can refer to either an individual pixel sensor device (e.g., a photo diode or a photo transistor), to the individual pixel sensor and an associated color filter, or collectively to the individual pixel sensor, the associated color filter, and an associated microlens. The individual pixel sensor device can be a photo diode or a photo transistor.

Newer industrial and consumer applications, for example, automotive applications such as advanced driver assistance systems (ADAS) and autonomous driving (AD) systems, can include other circuitry in the same integrated circuit (IC) package as the optical sensor die for improved imaging performance. The other circuitry may include an optical signal processor (ISP) or an application specific integrated circuit (ASIC). The ISP or the ASIC die, can be coupled to, or combined with the optical sensor die in a package. In example implementations, an IMD layer that is disposed on the optical sensor die and or the ASIC die may include at least a metal level of a redistribution layer of the optical sensor die.

The devices of an optical sensor package may be fabricated in a semiconductor die (optical sensor die), for example, by wafer-level processing steps, and coupled to circuitry such as an ASIC. The ASIC can include, for example, a driver circuit and an A/D converter. The ASIC circuits may be fabricated on a same semiconductor die as the devices for detecting light intensity, or on a separate ASIC die coupled to the optical sensor die. In some implementations, the optical sensor package in a hybrid die package configuration may include multiple semiconductor dies of diverse types. For example, in the hybrid die package configuration, the optical sensor package may include a silicon carbide (SiC) device die and a silicon device die.

This disclosure describes an optical sensor package (e.g., a ball grid array (BGA) package) in which a semiconductor optical sensor die is mounted on an amorphous (non-crystalline) solid inorganic substrate. The inorganic substrate may, for example, be a silicate-based substrate (e.g., a glass substrate). In example implementations, the inorganic substrate may be a borosilicate glass (such as Pyrex or Kimax). The borosilicate glass substrate may have a coefficient of thermal expansion (CTE) of about 3 ppm/K. In contrast, plastic, or organic substrates (e.g., BT substrates) that are used, for example, in iBGA packages, have CTEs of about 10 to 14 ppm/K. The low CTE and the rigidity of the silicate-based substrates in the disclosed optical sensor packages may help avoid issues with die tilt and package warp that are seen, for example, in packages which use plastic or organic substrates (such as in iBGA packages).

The optical sensor package may include one or more signal redistribution layers to route signals and power within the dies and within the package. A signal redistribution layer (RDL) can redistribute I/O connections from the optical sensor die and the package. A RDL structure may include multiple layers of metal traces, insulating materials, and vias for proper signal routing and protection.

In example implementations, an optical sensor die is disposed on a top surface of a glass substrate. In some example implementations, the optical sensor die is disposed in a recess in the top surface of the glass substrate. Further the optical sensor die may be wire bonded to traces or pads disposed on the glass substrate. The wire bonds may connect the optical sensor die to the lead frames or the external terminals of the package. The traces or pads (e.g., metal traces or pads) may be included in an inter-metal dielectric (IMD) layer disposed adjacent to the optical sensor die on the top surface of the glass substrate. The IMD layer can form portions of one, two, or several RDLs of the package.

The glass substrate can include a plurality of through-glass vias (TGVs). Some of the TGVs may be filled or lined, for example, with electrically conductive material and provide electrical connections between the optical sensor die and a ball grid array disposed on a bottom surface of the glass substrate. Some of the plurality of TGVs may be purposed for heat dissipation and or for strength uniformity across the glass substrate.

In example implementations, a glass cover (lid) may be disposed above the optical sensor die. The glass cover may be supported above the optical sensor die by dam (wall) made of mold material disposed along edges of the glass substrate or along edges the optical sensor die. In example implementations, the glass cover may be transparent to light over at least a portion of a range of wavelengths detected or sensed by the OASA of the optical sensor die.

In example implementations, the mold material may be entirely outside the area of the optical sensor die, while in some other example implementations, the mold material may partially overlap a top surface of the optical sensor die.

In some instances, the glass cover may form an air cavity above the optical sensor die. In some instances, for very large die (e.g., a 15 Mega Pixel (MP), 2.1 um pixel die, having a size of about 12.2 mm×7.2 mm=87 mm²), the glass cover may include holes or vents to prevent buildup of air pressure in the air cavity above the optical sensor die. The holes or vents may have sufficiently small cross-sectional areas (e.g., diameters) such that surface tension precludes ingress of external fluids into the air cavity. In some example implementations, the glass cover may be placed in direct contact with the optical sensor die such that no air gap or air cavity is formed above the optical sensor die.

In example implementations, the glass cover may have about the same lateral dimensions as the glass substrate. In some example implementations, the glass cover may have lateral dimensions that are smaller than the lateral dimensions of the glass substrate.

In example implementations, the glass cover may have about the same lateral dimensions as the optical sensor die. In some example implementations, the glass cover may have lateral dimensions that are same as or smaller than the lateral dimensions of the optical sensor die.

In example implementations, sides of the optical sensor die and sides of the glass substrate are both covered with an encapsulant. In example implementations, only sides of the glass substrate are covered by the encapsulant. Wire bonds between the optical sensor die and the top surface of the glass substrate also may be covered by the encapsulant.

In some example implementations, the wire bonds may be covered by the mold material of the wall or dam supporting the glass cover above the optical sensor die.

The mold material of the wall or dam disposed around the optical sensor die may be non-transparent (e.g., having a black color) with high absorption and low reflection of visible and infrared light. This may help mitigate flare in the optical sensor die package. Further, in some implementations, a black dielectric (with high absorption and low reflection of visible and infrared light) may be patterned along edges of the glass cover. This may also help mitigate flare in the optical sensor die package.

In some example implementations, an optical sensor converts light rays into an electronic signal. The purpose of an optical sensor is to measure a physical quantity of light and, depending on the type of sensor, translate the physical quantity of light into a form that is readable by an integrated measuring device. An optical sensor used as an image sensor or imager is a sensor that detects and conveys information used to form an image. Optical sensors are used in electronic imaging devices of both analog and digital types, which include digital cameras, camera modules, camera phones, optical mouse devices, medical imaging equipment, night vision equipment such as thermal imaging devices, radar, sonar, etc. As technology changes, electronic and digital imaging tends to replace chemical and analog imaging. The two main types of digital image sensors are the charge-coupled device (CCD) and the active-pixel sensor (CMOS sensor), fabricated in complementary MOS (CMOS) or N-type MOS (NMOS) technologies.

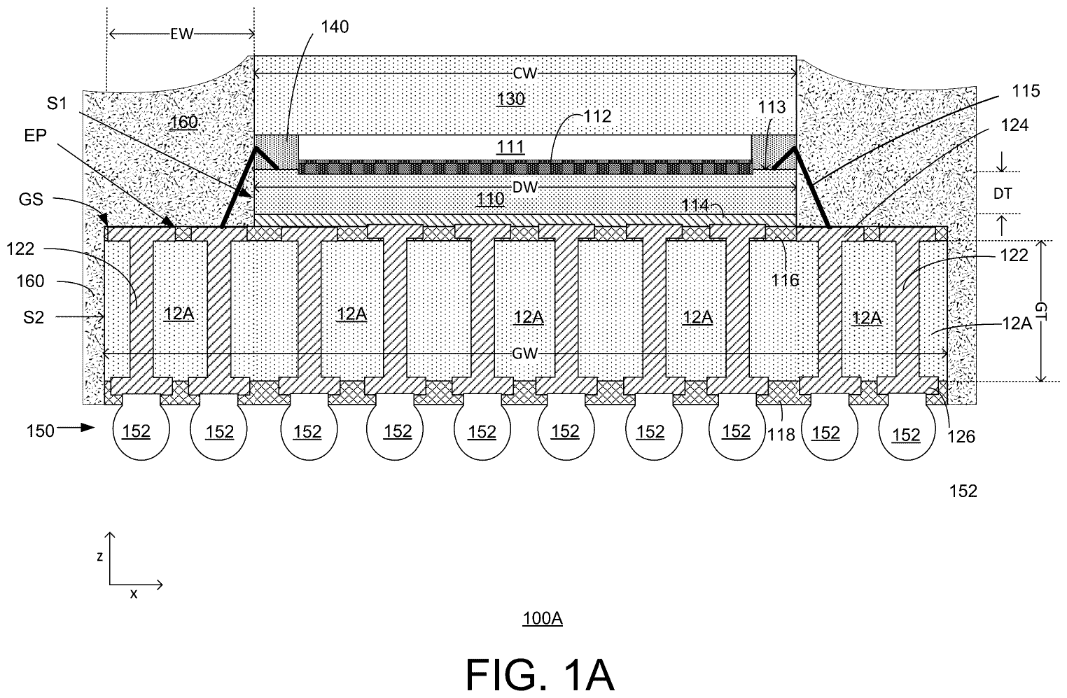

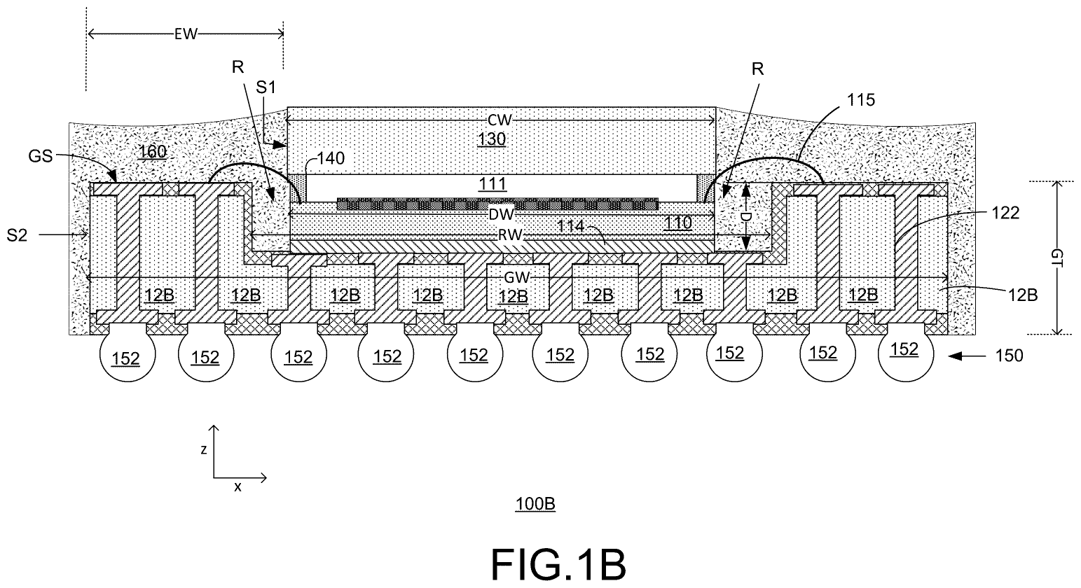

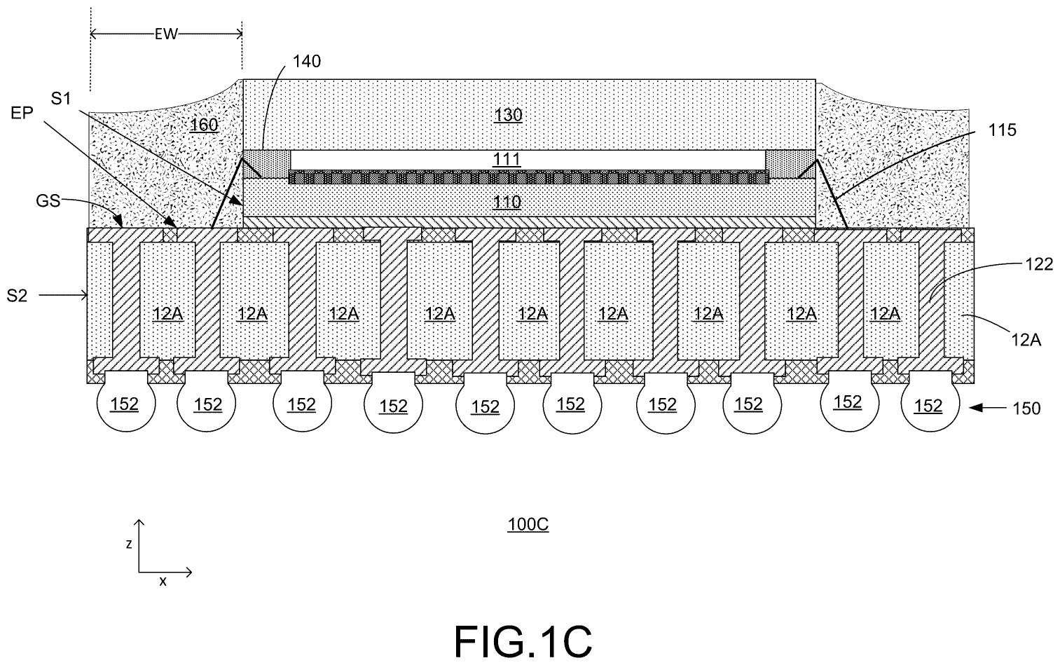

FIG. 1A shows a cross-sectional view of an optical sensor package 100A in which an optical sensor die 110 is disposed on a glass substrate 12A, in accordance with the principles of the present disclosure.

Optical sensor die 110 may, for example, be a semiconductor die with an optically active surface area (e.g., OASA 112) fabricated on a top surface of a slab of semiconductor material. The slab of semiconductor material may, for example, have a thickness DT (in the z direction) and a width DW (e.g., in an x direction). The slab of semiconductor material may, for example, be silicon. OASA 112 may occupy a portion of the surface area of the semiconductor die. Portions of the surface area adjacent to OASA 112 may include device contact pads (e.g., pad 113) making electrical connection to devices in optical sensor die 110.

Glass substrate 12A may, for example, be a rectangular piece (also can be referred to as a portion) of glass with a thickness GT (e.g., in the z direction) and a width GW (e.g., in the x direction). Glass substrate 12A may, for example, be a borosilicate glass. An inter-metal dielectric (IMD) layer 116 may be disposed on a top surface GS of glass substrate 12A. IMD layer 116 may include conductive traces or pads (e.g., metal pads 124) that can form portions of one, two, or more signal redistribution layers for optical sensor die 110. Further, an inter-metal dielectric (IMD) layer 118 may be disposed on a bottom surface SB of glass substrate 12A. IMD layer 118 may include a plurality of pads (e.g., metal pads 126). Solder balls (e.g., solder ball 152) may be attached to metal pads 126 to form a ball grid array (e.g., BGA 150) as the external terminal contacts of optical sensor package 100A. IMD layer 118 can form portions of one, two, or more signal redistribution layers for optical sensor die 110 on the bottom side of glass substrate 12A. A plurality of through-substrate vias (e.g., through glass vias, TGV 122) filled with conductive material may connect metal pads 124 on the top surface of glass substrate 12A to metal pads 126 on the bottom surface of glass substrate 12A. In example implementations, the conductive material included in (filling or lining) TGV 122 may be a metal or a metal alloy (e.g., copper).

In example implementations of the package, the first inter-metal dielectric layer and the second inter-metal dielectric layer, and the at least one through-substrate via filled with conductive material, may form portions of a signal redistribution layer for the optical sensor die in the package. In example implementations, the signal redistribution layer is a first signal redistribution layer, and the package further includes a second signal redistribution layer for the optical sensor die in the package. In example implementations, the package may further include multiple signal redistribution layers for the optical sensor die and other dies in the package.

In optical sensor package 100A, a die attach pad or area may be formed by a layer of adhesive 114 disposed on the top surface of glass substrate 12A. Optical sensor die 110 may be placed on this die attach area and attached to the glass substrate 12A by the layer of adhesive 114.

In example implementations, optical sensor die may have a smaller area than the area of glass substrate 12A (e.g., die width DW may be less than glass substrate width GW). An edge portion (EP) of glass substrate 12A (extending, for example, from a side S1 of the die to a side S2 of the glass substrate) may not be covered by the die. Edge portion EP may, for example, have a width EW (e.g., in the x direction).

Further, wire bonds (e.g., wire bond 115) may connect the device contact pads (e.g., pad 113) on the surface of the die to the conductive traces or pads (e.g., metal pads 124) in IMD layer 116 exposed on the surface in edge portion EP of glass substrate 12A. The wire bonds (e.g., wire bond 115) may provide electrical connectivity from the device contact pads (e.g., pad 113) to the solder balls (e.g., solder ball 152) that form the external terminals of the ball grid array package through the conductive material-filled TGVs 122. In example implementations, wire bond 115 may be a copper or an aluminum wire.

In some implementations, a protective glass cover or lid (e.g., glass cover 130) may be placed over optical sensor die 110, for example, to protect OASA from the elements (e.g., dust particles or projectiles) in the ambience. In example implementations, glass cover 130 may have a width GW, which is about the same as width DW of die 110, but is smaller than the glass substrate width GW. As shown in FIG. 1A, a dam or supporting wall (e.g., dam 140) may be formed on optical sensor die along the edges of the die (e.g., over pad 113). Dam 140 may be made, for example, of adhesive mold material. Glass cover 130 may be supported over the optical sensor die by dam 140. Glass cover 130 may have a width CW (e.g., in the x direction) which may be about the same as the width DW of the optical sensor die. In example implementations, glass cover 130 may enclose an air cavity 111 above the optical sensor die.

In example implementations, as shown in FIG. 1A, dam 140 may encapsulate portions of wire bond 115 above the optical sensor die.

Furthermore, in example implementations, the optical sensor package may include an encapsulant material (e.g., encapsulating material 160) that encapsulates at least some components or portions of the optical sensor package.

In the example optical sensor package 100A shown in FIG. 1A, encapsulating material 160 (e.g., an epoxy or electronic molding compound) is disposed on edge portion EP of glass substrate 12A along sides (e.g., side S1) of optical sensor die 110 and glass cover 130. Encapsulating material 160 is also disposed on the sides (e.g., side S2) of glass substrate 12A that are outside the edge portion EP of glass substrate 12A.

In the example optical sensor package 100A shown in FIG. 1A, optical sensor die 110 is disposed on a glass substrate 12A that has a substantially uniform thickness GT across its width GW (in other words, glass substrate 12A has a substantially planar surface across its width GW). Optical sensor die 110 is disposed on this substantially planar glass substrate surface. In some example optical sensor package implementations, a top surface of a glass substrate may have recess in which optical sensor die 110 can be disposed.

FIG. 1B shows a cross sectional view of an optical sensor package 100B, in which optical sensor die 110 is disposed in a recess in the surface of a glass substrate, in accordance with the principles of the present disclosure.

Optical sensor package 100B may be based on a glass substrate 12B. Glass substrate 12B may, for example, be like glass substrate 12A (FIG. 1A), be a rectangular slab of glass with a thickness GT (e.g., in the z direction) and a width GW (e.g., in the x direction). Glass substrate 12B may have a recess R in its top surface GS. Recess may, for example, have a depth D and a width RW. Width RW may be greater than the width DW of optical sensor die 12B. Optical sensor die 12B may be placed in recess R and attached to glass substrate 12B by layer of adhesive 114. Placing the optical sensor die 110 in recess R (instead of on the surface of the glass substrate as in FIG. 1A) enables optical sensor package 100B (FIG. 1B) to have a thinner shape form factor than optical sensor package 100A (FIG. 1A).

In the example optical sensor package 100A shown in FIG. 1A encapsulating material 160 is disposed on edge portion EP of glass substrate 12A along sides (e.g., side S1) of optical sensor die 110 and glass cover 130, and is also disposed on sides (e.g., side S2) of glass substrate 12A that are outside the edge portion EP of glass substrate 12A. Similarly, in the example optical sensor package 100B shown in FIG. 1B, encapsulating material 160 is disposed on edge portion EP of glass substrate 12B in recess R along sides (e.g., side S1) of optical sensor die 110 and glass cover 130, and is also disposed on sides (e.g., side S2) of glass substrate 12B that are outside the edge portion EP of glass substrate 12B. In some example implementations, the encapsulating material may encapsulate fewer portions or components of the optical sensor package. FIG. 1C shows, for example, an optical sensor package 100C in which encapsulating material 160 is disposed only on edge portion EP of glass substrate 12A along sides (e.g., side S1) of optical sensor die 110 and glass cover 130. No encapsulating material 160 is disposed on sides (e.g., side S2) of glass substrate 12A (in other words, sides of the glass substrate are not encapsulated).

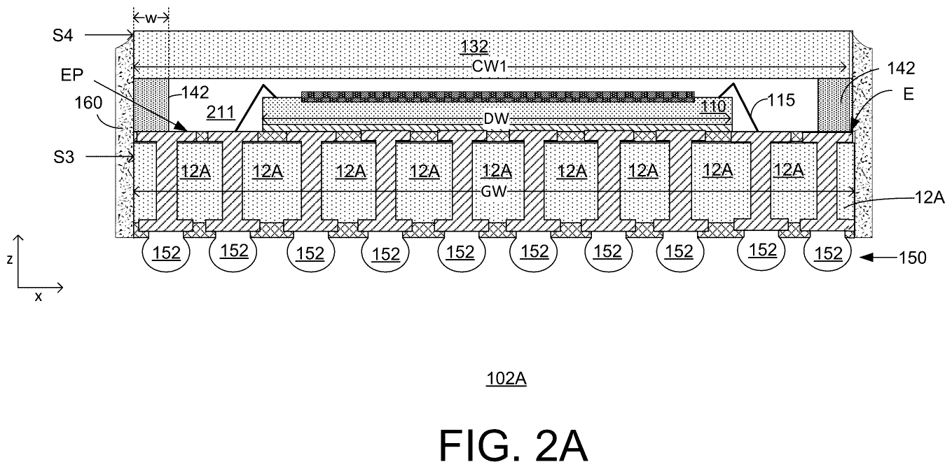

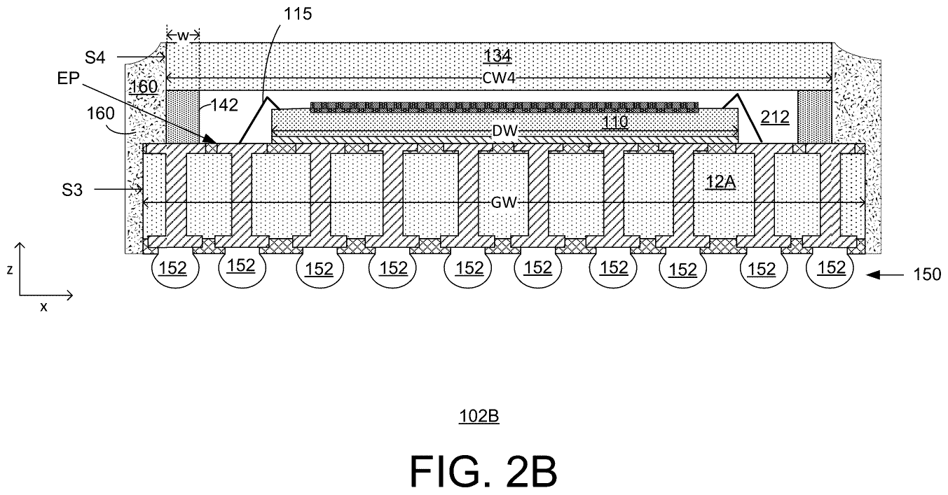

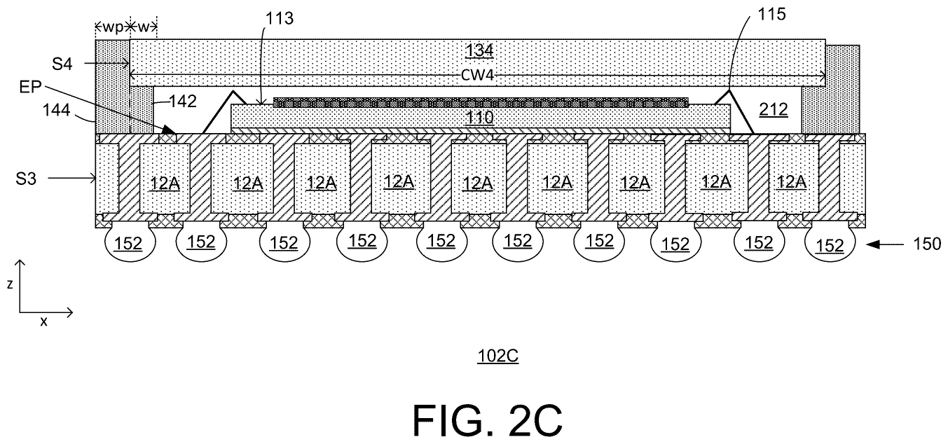

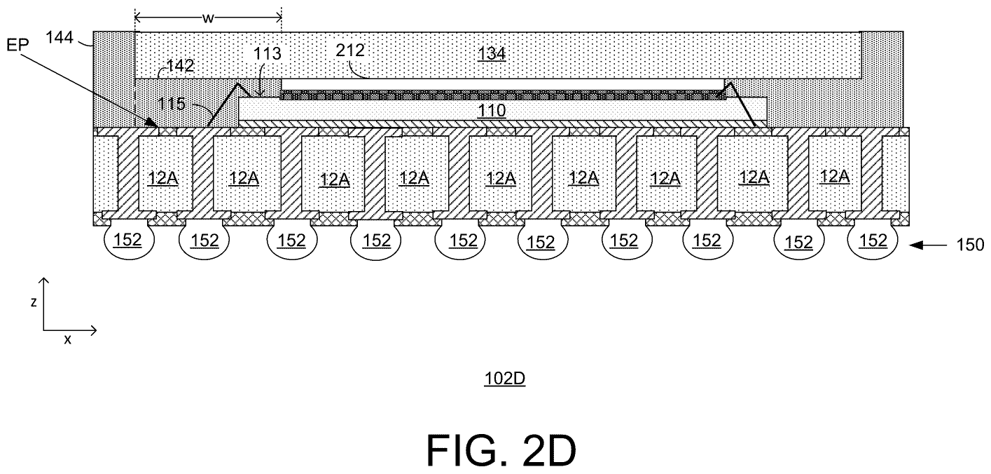

In the example optical sensor packages 100A, 100B, and 100C (shown in FIG. 1A, FIG. 1B, and FIG. 1C, respectively), the glass cover (e.g., glass cover 130) has a width CW that is about the same as the width DW of die 110 but is smaller than the width GW of the glass substrate. In some example implementations, the glass cover may have a width greater than the width DW of die 110. FIGS. 2A, 2B, 2C and 2D illustrate example optical sensor packages in which a glass cover above an optical sensor die is as wide or almost as wide as a glass substrate on which the optical sensor die is disposed, in accordance with the principles of the present disclosure.

FIG. 2A shows, for example, an example optical sensor package 102A in which glass cover 132 has width CW1 (in the x-direction) that is greater than the width DW of die 110. As shown in FIG. 2A, the width CW1 of glass cover 130 may be the same or about the same as the width GW of glass substrate 12A. Glass cover 132 may be supported above die 110 by a wall or dam 142 formed along edge E of glass substrate 12A. Wall or dam 142 (like dam 140, FIG. 1A) may be made of adhesive (mold) material. Dam 142 may, for example, have a width w (in the x-direction). Glass cover 132 supported on dam 142 may enclose an air cavity may enclose an air cavity 211 above die 110 extending between the dams 142 on which the glass cover is supported. Air cavity 211 may have a width in the x-direction of about the width of the glass substrate less the width of the dams on two sides (e.g., =(GW−2*w)) and extend above die 110 and over portion EP of the glass substrate adjacent to die 110. Wire bonds 115 may extend between die 110 and substrate 12A through the air in air cavity 211 without touching or contacting any mold or encapsulating material. Encapsulating material 160 may be disposed alongside (side S3) of the glass substrate and alongside (side S4) glass cover 132.

In another example implementation, the glass cover (e.g., glass cover 134) may have a width that is greater than the width DW of die 110 but is smaller than the width GW of the glass substrate.

FIG. 2B shows, for example, an example optical sensor package 102B in which a glass cover 134 has width CW4, which is greater than the width DW of die 110 but is smaller than the width GW of glass substrate 12A. Glass cover 134 may be supported above die 110 by wall or dam 142 formed within edge portion EP of glass substrate 12A. Glass cover 134 supported on dam 142 may enclose an air cavity 212 above die 110 extending between the dams 142 on which the glass cover is supported. Air cavity 212 may extend above die 110 and over portions EP of the glass substrate adjacent to die 110. Air cavity 212 may have a width in the x-direction of about the width of glass cover less the widths of the dams on two sides of the glass cover (e.g., air cavity 212 width=(CW4−2*w)). Encapsulating material 160 may be disposed alongside (side S3) of the glass substrate and alongside (side S4) glass cover 132 on exposed portions EP of the glass substrate.

In some example implementations, in an optical sensor package, the sides of the glass substrate may not be encapsulated. Only sides of the glass cover may be encapsulated. FIG. 2C shows, for example, an example optical sensor package 102C in which (like in optical sensor package 102B, FIG. 2B), a glass cover 134 has width CW4, which is greater than the width DW of die 110 but is smaller than the width GW of glass substrate 12A. Glass cover 134 may be supported above die 110 by a wall or dam 142 formed within edge portion EP of glass substrate 12A. As shown in FIG. 2C, no encapsulating material 160 is applied to sides S3 of glass substrate 12A. However, encapsulating material (e.g., dam 144) may be disposed alongside (side S4) of glass cover 132 on exposed portions EP of the glass substrate that are not directly below the glass cover to encapsulate the sides of the glass cover.

Encapsulating material used for dam 144 may be the same material (e.g., an epoxy or a molding compound) as encapsulating material 160 or the same material used as the adhesive dam material in dam 140 or dam 142.

In some example implementations of an optical sensor package, the material of the dam (e.g., dam 140 or dam 142) on which the glass cover is placed may extend over portion EP of the glass substrate and over portions of the die to encapsulate wire bonds 15. FIG. 2D shows, for example, an example optical sensor package 102D in which a glass cover 134 has width CW4, which is greater than the width of die 110 but is smaller than the width of glass substrate 12A. Glass cover 134 may be supported above die 110 by wall or dam 142 formed on edge portion EP of glass substrate 12A. Wall or dam 142 may extend underneath the glass cover to the edges of die 110 and over the device contact pads (e.g., pad 113) on the top surface of the die. The materials of dam 142 in this configuration may encapsulate wire bonds 115 formed between pad 113 and the traces or and pads on the surface of glass substrate 12A.

In example implementations of an optical sensor package in which a glass cover is disposed above optical sensor die 110 enclosing the die in an air cavity, at least one air vent hole may be disposed in the body of the glass cover. The air vent hole may provide a path for air flow between the air cavity enclosing the optical sensor die 110 and the ambience of the optical sensor package. The air vent hole (or holes) may prevent buildup of air pressure in the air cavity above the optical sensor. The air vent size (e.g., hole diameter) may be sufficiently small so that the surface tension of an external fluid (e.g., water, alcohol, etc.) will prevent the external fluid from entering the cavity through the air vent hole.

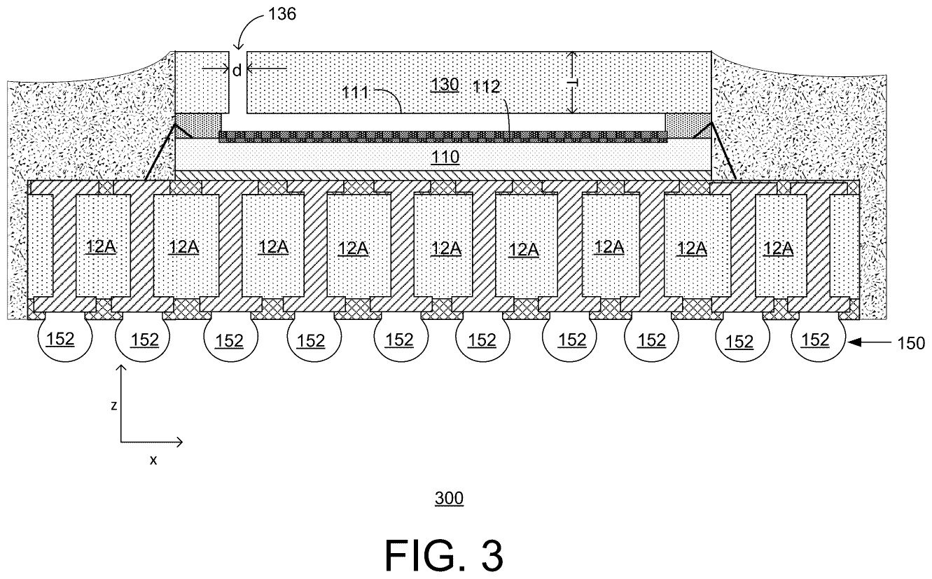

For example, FIG. 3 shows a cross-sectional view of an optical sensor package 300 in which, like in optical sensor package 100A (FIG. 1A), glass cover 130 is disposed above optical sensor die 110 and forms air cavity 111 above the die. Glass cover 130 in optical sensor package 300 includes an air vent or passageway (e.g., hole 136) which extends vertically through a thickness T of the glass cover 130. Hole 136, which may have a diameter d, connects air cavity 111 to the outside of optical sensor package 300. Hole 136 may prevent a buildup of air pressure in the air cavity above the sensor. The diameter d of hole 136 is small to prevent external fluids from entering the cavity because of the surface tension of the fluids.

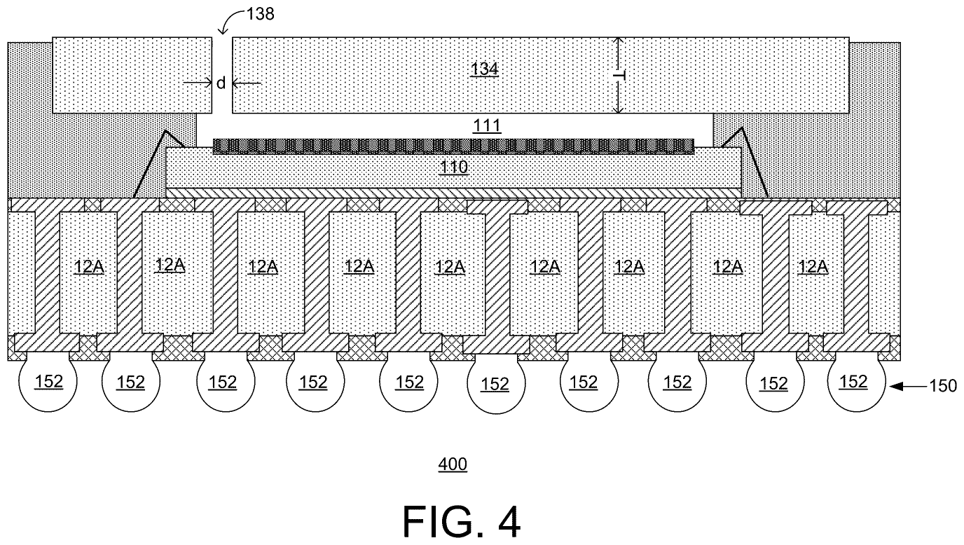

Further, for example, FIG. 4 shows a cross-sectional view of an optical sensor package 400, in which like in optical sensor package 102D (FIG. 2D), glass cover 134 is disposed above optical sensor die 110 and forms air cavity 212 above the die. Glass cover 134 in optical sensor package 400 includes air vent or hole 138, which extends vertically through a thickness T of the glass cover 134. Air vent hole 138, which may have a diameter d, connects air cavity 211 to the outside of optical sensor package 400. Air vent hole 138 may prevent a buildup of air pressure in the air cavity above the sensor. The diameter d of air vent hole 138 is small to prevent external fluids from entering the cavity because of the surface tension of the fluids.

In some implementations, the optical sensor packages described herein may include features that eliminate or reduce occurrences of flare in images collected by the optical sensor die in the package. For example, in some implementations, a black color mask or coating (with high absorption and low reflection of visible and infrared light) may be disposed on the underside of the edges of the glass cover.

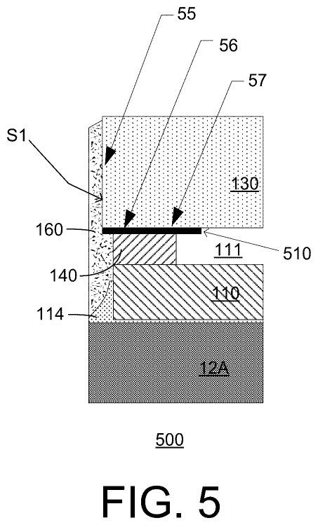

FIG. 5 shows an exploded view of a corner portion of an optical sensor package 500 with a black-under-glass (BuG) feature (e.g., a black mask).

Optical sensor package 500 may (like optical sensor package 100A, FIG. 1A) include an optical sensor die 110 disposed on layer of adhesive 114 on glass substrate 12A. A glass cover 130 may be disposed above the die to enclose air cavity 111. Glass cover 130 may rest on a wall or dam 140 made of adhesive mold material. Encapsulating material 160 may be disposed on a side (S1) of the die and the glass cover.

As shown in FIG. 5, a black mask 510 may be patterned under glass cover 130 (e.g., at the edges of glass cover 130). Black mask 510 may be formed by a paint, an epoxy, a dielectric, or other non-transparent material with high absorption and low reflection of visible and infrared light.

In FIG. 5, stray light that may cause flare is represented, for example, as light rays with numbered arrows 55, 56, and 57. The stray light that may cause flare includes, for example: light ray 55 incident on the glass cover edge; light ray incident 56 incident on the glass adhesive; and light ray 57 incident on the glass adhesive edge. Black mask 510 may absorb and prevent scattering of these light rays on to the OASA of the optical sensor die to prevent occurrences of flare.

In some example implementations, in addition to, or as an alternate to, the black-under-glass (BuG) feature, the walls or dams (e.g., dam 140, dam 142) may be made of black color material (adhesive mold material). The black color material may have a high absorption and a low reflection of visible and infrared light. The black color material of the dams (e.g., dam 142 and 144) may help mitigate occurrences of flare in the optical sensor die package.

In example implementations, the optical sensor packages described herein may be fabricated using wafer-level processes and or die-level processes.

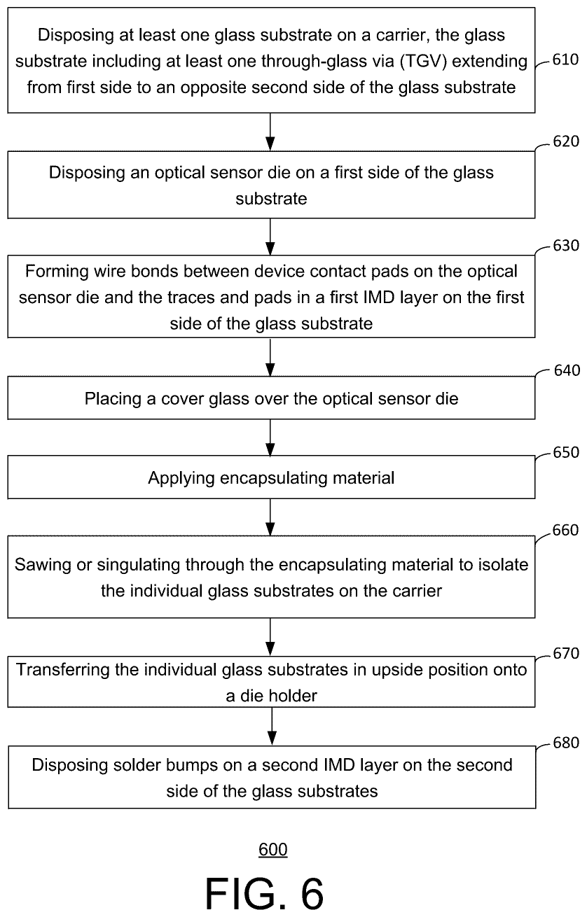

FIG. 6 shows an example method 600 that involves die-level processes for disposing semiconductor optical die on a glass substrate in an optical sensor package. The package may be configured as a ball grid array package with solder balls forming the external electrical contacts or terminals of the package (e.g., optical sensor package 100A, FIG. 1A).

Method 600 includes disposing at least one glass substrate on a carrier (610). The glass substrate can include at least one through-glass via (TGV) extending from a first side to an opposite second side of the glass substrate. The glass substrate may be a piece of glass sized for an individual optical sensor die. The glass substrate may be a piece of glass having a same size or a size larger than an individual optical sensor die. The glass substrate may be prepared with a first inter-metal dielectric (IMD) layer disposed on a first side of the glass substrate The first IMD layer may include traces and pads of a redistribution layer for the optical sensor die. A second IMD layer may be disposed on an opposite second side of the glass substrate. A second IMD layer may include traces and pads of a redistribution layer for the optical sensor die. The second IMD layer may include conductive pads configured to receive solder balls for the ball grid array of the optical sensor package glass substrate. The glass substrate may include conductive material-filled through-glass vias (TGVs) that can electrically connect the first IMD layer and the second IMD layer. The conductive material in the TGVs may, for example, be a metal, copper, aluminum, or a metal alloy.

In method 600, the carrier on which the glass substrate is disposed may, for example, be a sheet of metal or ceramic. The glass substrate may be attached to the carrier with a temporary adhesive.

In some instances, the at least one glass substrate may be a plurality of glass substrates (e.g., 2-1000) disposed on the carrier.

Next, method 600 includes disposing an optical sensor die on the first side of the glass substrate (620). The optical sensor die may be disposed on an adhesive layer in a die attach area on the first side of the glass substrate. Method 600 further includes forming wire bonds between device contact pads on the optical sensor die and the traces and pads in a first IMD layer on the first side of the glass substrate (630); and placing a glass cover over the optical sensor die (640). The glass cover may be attached using a glass attach adhesive applied over the wire bonds. Next, method 600 includes applying encapsulating material (650). The encapsulating material may be applied, for example, on the (exposed) vertical sides of the glass cover, the optical sensor die, and the glass substrate. In instances where several glass substrates are disposed on the carrier, the applied encapsulating material may join the several individual glass substrates together.

Method 600 further includes sawing or singulating through the encapsulating material to isolate the individual glass substrates on the carrier (660). Each individual glass substrate, at this stage of the process, includes a wire bonded optical sensor die disposed on its surface.

Method 600 further includes transferring the individual glass substrates from the carrier to an upside down position on a die holder (670). In the upside down position, the second IMD layer is at the top of the die. Method 600 further includes disposing solder bumps on the second IMD layer on the second side of the glass substrates (680). Disposing solder bumps may include solder reflow processes to form a ball grid array for the external electrical contacts or terminals of the package (e.g., optical sensor package 100A, FIG. 1A).

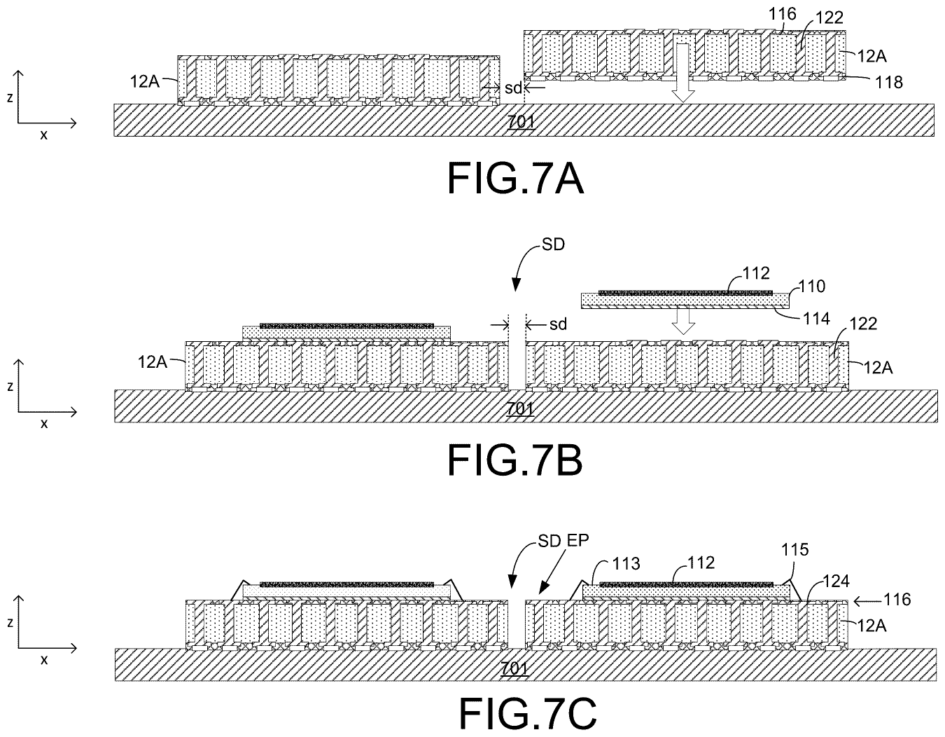

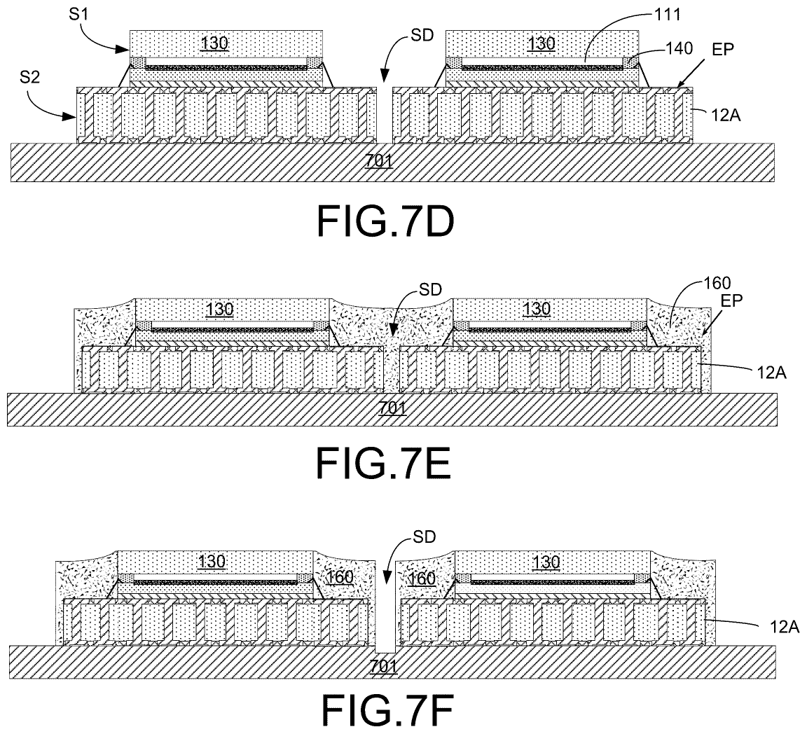

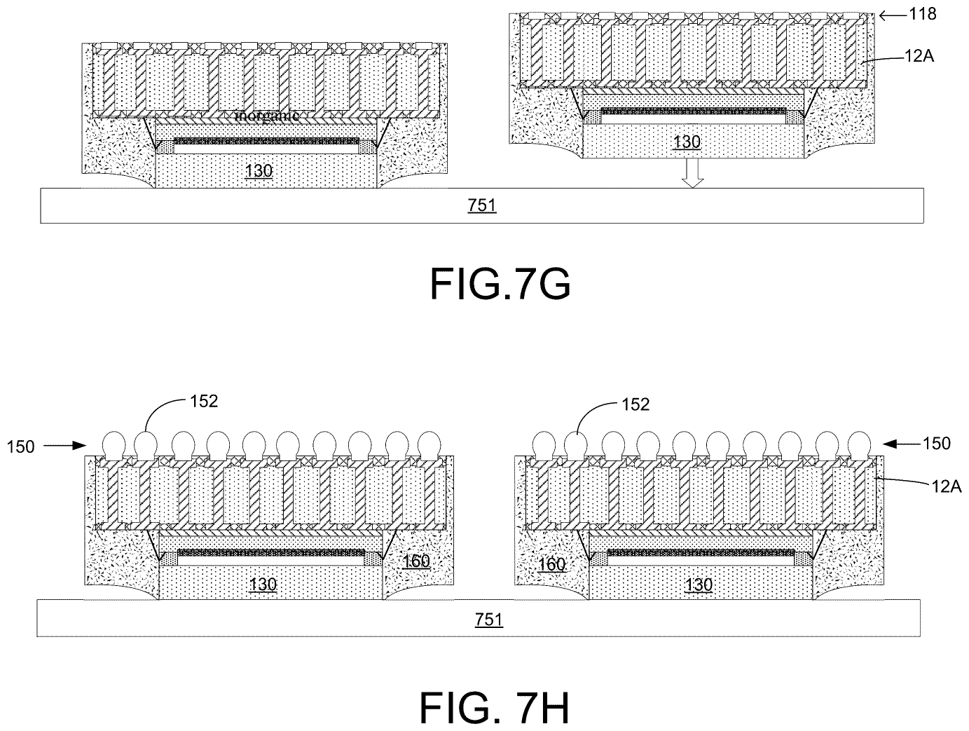

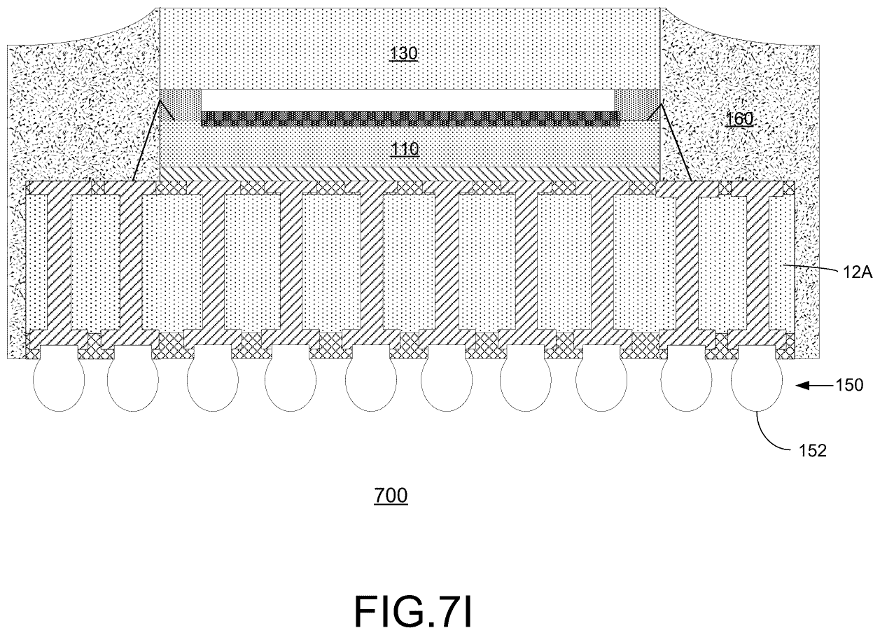

FIGS. 7A through 7I illustrate cross-sectional views of a glass substrate being processed through multiple steps of a process for making an optical sensor package (e.g., according to method 600, FIG. 6).

FIG. 7A shows, for example, an initial stage of the process, a carrier 701 on which a plurality of glass substrates (e.g., substrate 12A, FIG. 1A) are placed. Carrier 701 may, for example, be a sheet of metal. Two neighboring substrates may be separated by a gap SD having a width sd (e.g., a distance sd in the x direction). A substrate 12A may be attached to carrier 701 by a temporary adhesive (not shown). The substrate 12A may, for example, be a piece of borosilicate glass with copper-filled or copper-lined TGVs 122. An IMD layer 116 and an IMD layer 118 may be disposed on a top surface and a bottom surface of the substrate, respectively. The copper-filled TGVs 122 may electrically connect IMD layer 116 and IMD layer 118.

FIG. 7B shows, for example, a next stage of the process, an optical sensor die 110 being placed on the glass substrate 12A on carrier 701. The optical sensor die may have an OASA 112 on a top surface of the die. The optical sensor die may be attached to the glass substrate by a layer of adhesive 114 applied, for example, to a bottom surface of the die.

Next as shown in FIG. 7C, wire bonds are formed between a device contact pad 113 adjacent to OASA 112 on the top surface of the die and the conductive traces or pads (e.g., metal pads 124) in IMD layer 116 exposed on the surface in edge portion EP of glass substrate 12A.

At a next stage of the process, as shown in FIG. 7D, a dam 140 is formed on the optical sensor die by, for example, dispensing an adhesive dam material above wire bond 115 along edges of the optical sensor die. Further, a glass cover 130 is placed over dam 140 enclosing an air cavity 111 above the optical sensor die.

Further, as shown in FIG. 7E, encapsulating material 160 may be applied to the sides of the substrates 12A (e.g., sides S2) and to the sides of the glass cover and the optical sensor die (e.g., sides S1). Encapsulating material 160 may extend over edge portion EP of glass substrate 12A and may also fill the gap SD between two neighboring substrates 12A.

Next, as shown in FIG. 7F, the assembly may be singulated or sawn through the encapsulating material in the gap SD between two neighboring substrates 12A to isolate the individual glass substrates on carrier 701. Further, as shown in FIG. 7G, the individual glass substrates may be transferred from the carrier to an upside down position on a die holder 751. In the upside down position, the second IMD (e.g., IMD layer 118) layer is at the top of the glass substrate on die holder 751.

Next, as shown in FIG. 7H, solder bumps 152 may be disposed on the second IMD layer. Disposing solder bumps may include solder reflow processes to form a ball grid array 150 for the external electrical contacts or terminals of the package (e.g., optical sensor package 700, FIG. 7I).

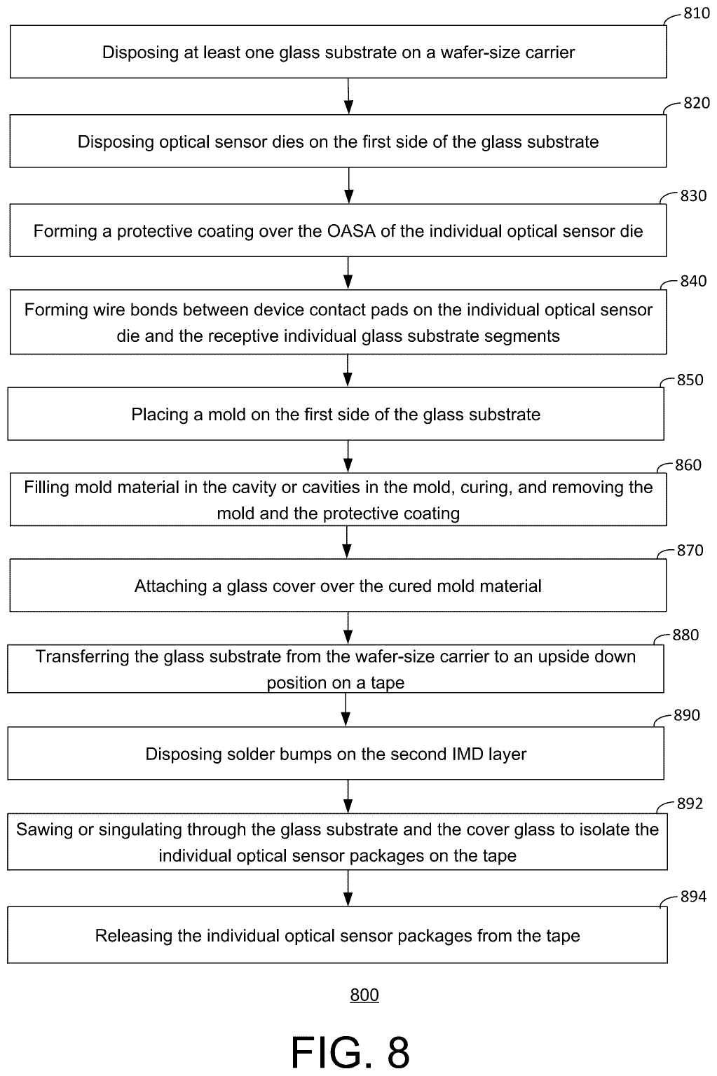

FIG. 8 shows an example method 800 that involves wafer-level processes for including optical sensor die supported on a glass substrate in an optical sensor package. Like in method 600, the resulting package may be configured as a ball grid array package with solder balls forming the external electrical contacts or terminals of the package (e.g., optical sensor package 200D, FIG. 2D).

Method 800 includes disposing a glass substrate on a wafer-size carrier (810). The wafer size-carrier may, for example, have a size compatible with that of a semiconductor wafer used in semiconductor device fabrication processes. The wafer-size carrier may, for example, be a wafer made of semiconductor material, a metal, or a ceramic. The glass substrate may be attached to the wafer-size carrier with a temporary adhesive.

The glass substrate may be a wafer-size piece of glass including a plurality of substrate segments. Each substrate segment may be sized to support an individual optical sensor die in an optical sensor package. The optical sensor die may, for example, be a 15 Mega Pixel (MP), 2.1 um pixel die, having a size of about 12.2 mm×7.2 mm=87 mm²,The glass substrate may be prepared with a first inter-metal dielectric (IMD) layer disposed on a first side of the glass substrate The first IMD layer may include traces and pads of a redistribution layer for the optical sensor die. A second inter-metal dielectric (IMD) layer may be disposed on an opposite second side of the glass substrate. The second IMD layer may include conductive pads configured to receive solder balls for the ball grid array of the optical sensor package. The glass substrate may include conductive material-filled through-glass vias (TGVs) that can electrically connect the first IMD layer and the second IMD layer.

Next, method 800 includes disposing optical sensor dies on the first side of the glass substrate (820). Individual optical sensor die may be disposed on respective individual glass substrate segments. Each individual optical sensor die may be disposed on an adhesive layer in a die attach area on the first side of the respective individual glass substrate segment.

Method 800 further includes forming a protective coating over the OASA of the individual optical sensor die (830). The protective coating may be applied, for example, by spray coating or spin coating a polymer or dielectric over the color filter array (CFA) and microlenses of the OASA of the dies.

Method 800 further includes forming wire bonds between device contact pads on the individual optical sensor die and the respective individual glass substrate segments. (840), and placing a mold above the assembly (850). The mold may have a cavity or cavities for receiving mold material (dam material) on the glass substrate in spaces between individual optical sensor dies and over the wire bonds. The mold may be made of aluminum, steel, or other metal. Method 800 includes filling (injecting) mold material cavity or cavities in the mold, curing, and removing the mold and the protective coating (860), and attaching a glass cover over the cured mold material (870). A glass attach adhesive may be used to attach the glass cover to the cured mold material.

Method 800 may further include transferring the glass substrate from the wafer-size carrier to an upside down position on a tape (880) (or another carrier). In the upside down position, the second IMD layer is at the top of the glass substrate and the glass cover may rest on the tape (or another carrier). Method 800 further includes disposing solder bumps on the second IMD layer (890). Disposing solder bumps may include solder reflow processes to form a ball grid array for the external electrical contacts or terminals of the packages (e.g., optical sensor package 102D, FIG. 2D).

Method 800 further includes sawing or singulating through the glass substrate and the glass cover to isolate the individual optical sensor packages on the tape (892), and releasing the individual optical sensor packages from the tape (894).

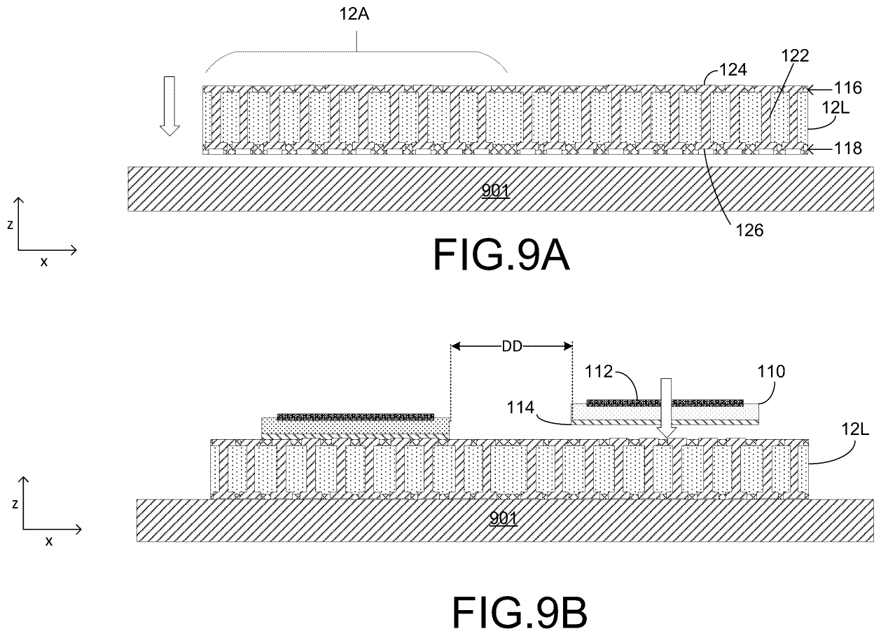

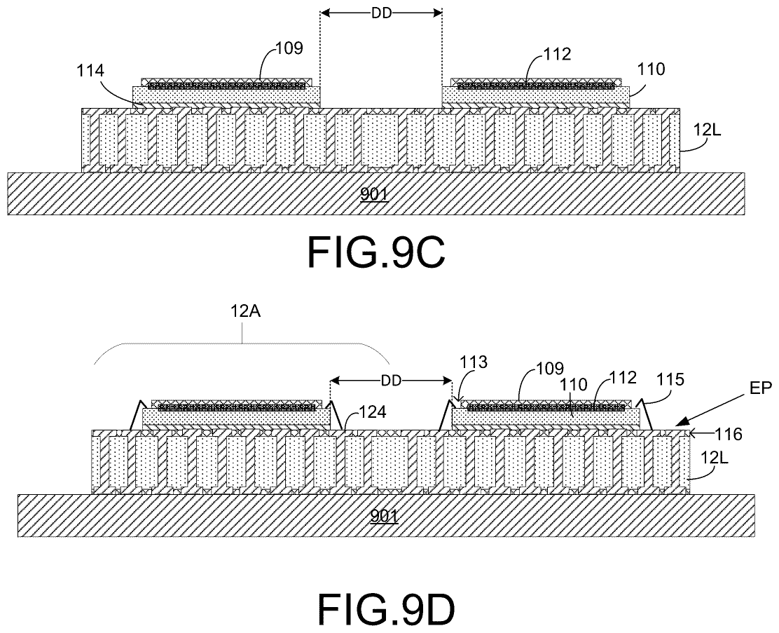

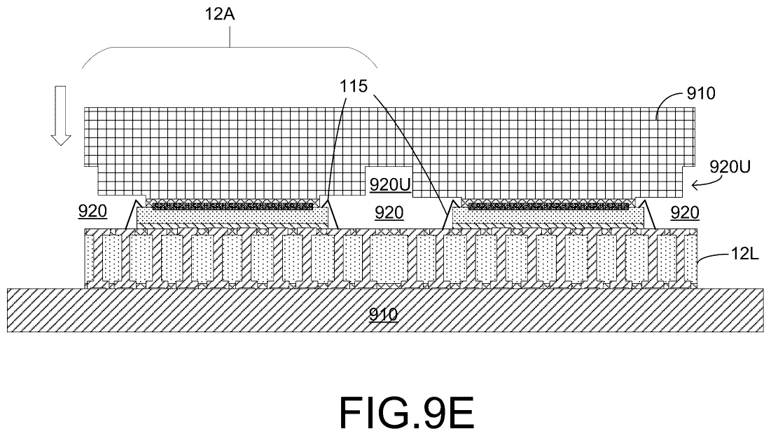

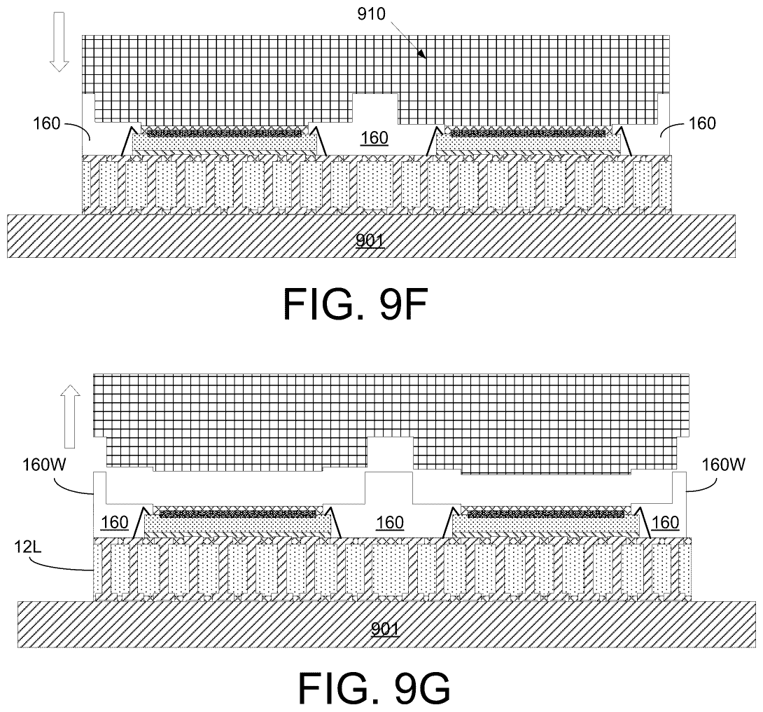

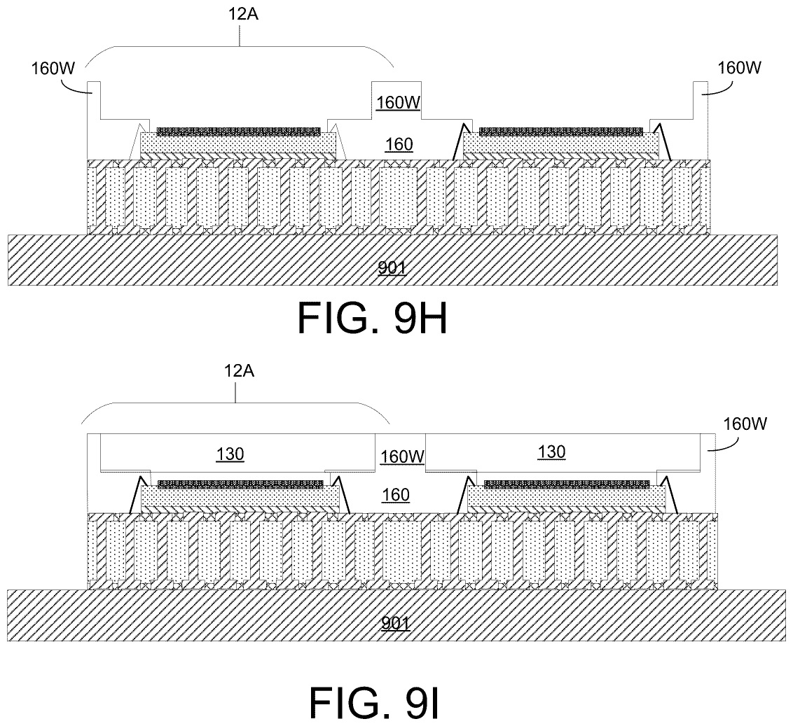

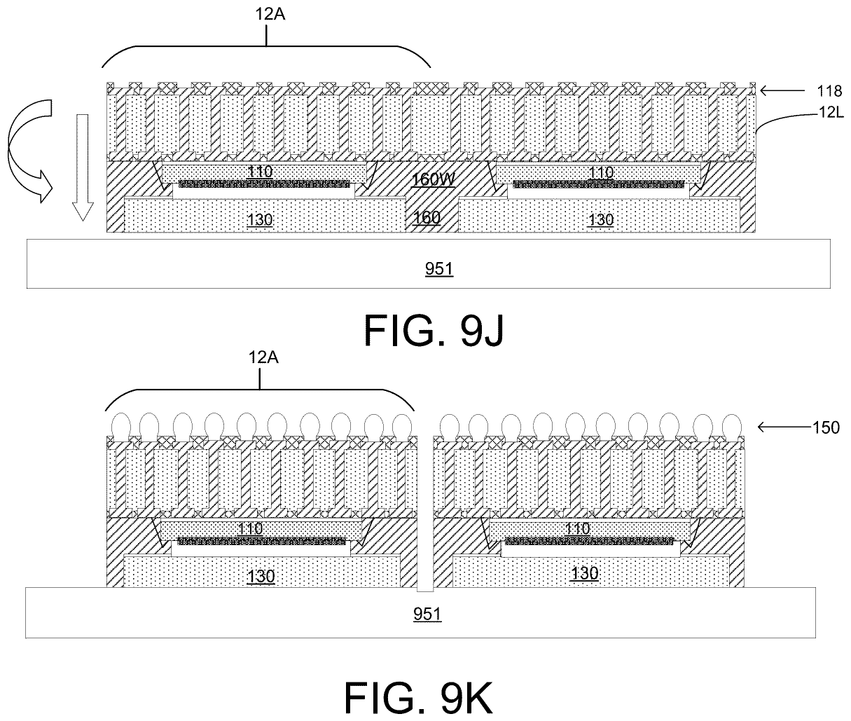

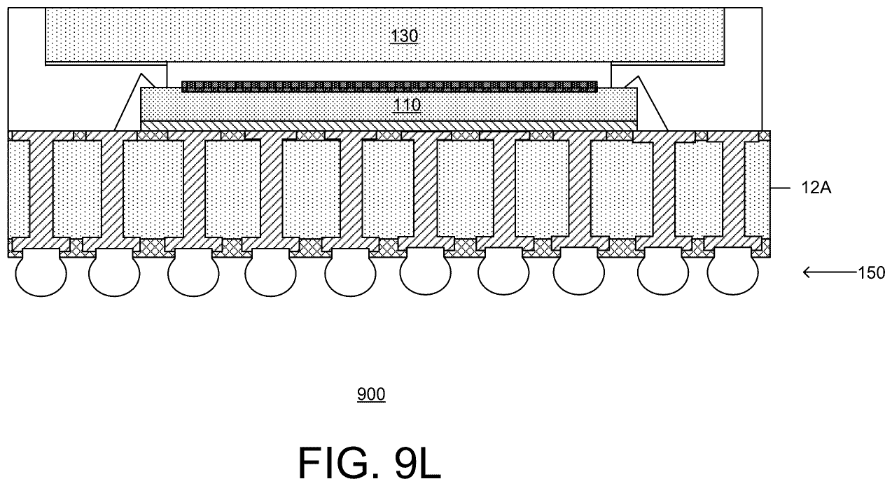

FIGS. 9A through 9L illustrate cross-sectional views of a glass substrate being processed through multiple process steps for making an optical sensor package, according to the method of FIG. 8.

FIG. 9A shows, for example, an initial stage of the process, a carrier 701 on which a glass substrate (e.g., substrate 12L) is placed on a carrier 901. Carrier 901 and substrate 12L may be of a large size (e.g., a wafer-size). Substrate 12L may, for example, include several substrate segments (e.g., substrates 12A, FIG. 1A) joined together as a single piece of glass. Substrate 12L may be attached to carrier 901 by a temporary adhesive (not shown). The substrate 12L may, for example, be a piece of borosilicate glass with copper-filled or copper-lined TGVs 122. An IMD layer 116 and an IMD layer 118 may be disposed on a top surface and a bottom surface of the substrate, respectively. The copper-filled TGVs 122 may electrically connect IMD layer 116 and IMD layer 118.

FIG. 9B shows, for example, at a next stage of the process, an optical sensor die 110 being placed on a segment of glass substrate 12L (e.g., on segment substrate 12A) on carrier 901. The optical sensor die may have an OASA 112 on a top surface of the die. The optical sensor die may be attached to the glass substrate by a layer of adhesive 114 applied, for example, to a bottom surface of the die. A plurality of optical sensor dies 110 may be placed on glass substrate 12L. A pair of neighboring dies may be separated by a distance DD (e.g., in the x direction).

Next, as shown in FIG. 9C, a protective coating 109 is formed over the OASA of the individual optical sensor die. The protective coating may be applied, for example, by spray coating or spin coating a polymer or dielectric over the color filter array (CFA) and microlenses of the OASA 112 of the dies.

Next, as shown in FIG. 9D, wire bonds 115 are formed between a device contact pad 113 adjacent to OASA 112 on the top surface of the die and the conductive traces or pads (e.g., metal pads 124) in IMD layer 116 exposed on the surface in edge portion EP of glass substrate 12A.

At a next stage of the process, as shown in FIG. 9E, a mold 910 is placed over the dies. The mold includes a cavity 920 extending above device contact pad 113 connected to the wire bonds 115. The cavity also extends over regions EP of the substrate between the two neighboring dies separated by distance DD (e.g., in the x direction). Portions of the cavity (e.g., cavity 920U) may also extend upward (in the z-direction) above the dies along the sides of substrate segments (substrate 12A).

Further, as shown in FIG. 9F, a mold material (e.g., encapsulating material 160, or mold material of dam 140) may fill cavity 920 and cavity 920U.

After curing, mold 910 may be removed as shown, for example, in FIG. 9G.

FIG. 9H shows a cross-sectional view of the assembly after mold 910 is removed. As a result of the molding operations, as shown in FIG. 9H, wire bond 115, and regions EP of the substrate between the two neighboring dies are encapsulated in encapsulating material 160. Further, based on the shape of cavity 920U in mold 910, dams or walls 160W are formed rising above the edges of the substrate segments (substrate 12A).

At a further stage in the process, as shown in FIG. 9I, a glass cover 130 is placed over the dies in each substrate segment (substrate 12A). The glass cover 130 may rest on mold material (encapsulating material 160) disposed on the wire bonds and the regions EP of the substrate between the two neighboring dies. In implementations where a permanent protective coating 109 is applied to the OASA of the dies, glass cover 130 may also rest on the permanent protective coating 109 that is applied to the OASA of the dies. In implementations where a temporary protective coating 109 is applied to the OASA of the dies, the temporary protective coating is removed (e.g., with an isopropyl alcohol (IPA) and or acetone solvent clean) before the glass cover 130 is attached on the mold material. A glass attach adhesive may be used to attach the glass cover to the cured mold material. In other implementations, glass cover 130 may enclose an air cavity above the OASA.

The dimensions (e.g., x dimensions) of the glass cover may be fitted (in the x direction) to match a distance between the walls (wall 160W) rising above the opposing edges of the substrate segments (substrate 12A) for a tight fit.

Further, as shown in FIG. 9J, the assembly of glass substrate 12L, the optical sensor dies 110 and glass covers (e.g., glass cover 130) may be transferred from carrier 901 and placed upside down on a tape (e.g., tape 951). In this upside position, the second IMD layer 118 is on the top of the assembly facing upwards (in the z direction).

Further, as shown in FIG. 9K, a next stage of processing may involve disposing solder balls on pads 126 in layer 118, and solder reflow, to form a solder ball grid array 150 for the external electrical contacts or terminals of the package (e.g., optical sensor package 900, FIG. 9L). Next, as also shown in FIG. 9K, the assembly may be singulated or sawn through to tape 951 between two neighboring substrate segments (substrate 12A) in glass substrate 12L to isolate the individual optical sensor packages on tape 951. FIG. 9L shows an optical sensor package 900 that may result from releasing the singulated assemblies from tape 951.

An example method includes disposing an inorganic substrate on a wafer-size carrier, the inorganic substrate including through-substrate vias filled with conductive material to electrically connect a first inter-metal dielectric layer disposed on a first side of the inorganic substrate and a second inter-metal dielectric layer disposed on a second side of the inorganic substrate.

The method further includes disposing optical sensor dies on the first side of the inorganic substrate with individual optical sensor die being disposed on a respective individual inorganic substrate segment, and forming wire bonds between device contact pads on the individual optical sensor die and the respective individual inorganic substrate segment.

The method further includes placing a mold on the first side of the inorganic substrate, the mold having have at least a cavity for receiving mold material in a space between the individual optical sensor dies and over the wire bonds, filling mold material in the cavity in the mold, curing, and removing the mold;

The method further includes attaching a cover over the cured mold material, transferring the inorganic substrate from the wafer-size carrier to an upside down position on a tape; and disposing solder bumps on the second inter-metal dielectric layer on the second side of the inorganic substrate.

Disposing solder bumps on the second inter-metal dielectric layer on the second side of the inorganic substrate includes solder reflow processes to form a ball grid array for making external electrical contacts optical sensor dies on the first side of the inorganic substrate.

The method further includes sawing or singulating through the inorganic substrate and the cover to isolate individual optical sensor packages on the tape and releasing the individual optical sensor packages from the tape.

Attaching the cover over the cured mold material includes forming a protective dielectric coating over an optically active surface area of the individual optical sensor die.

While certain features of the described implementations have been illustrated as described herein, many modifications, substitutions, changes, and equivalents will now occur to those skilled in the art. It is, therefore, to be understood that the appended claims are intended to cover all such modifications and changes as fall within the scope of the implementations. It should be understood that they have been presented by way of example only, not limitation, and various changes in form and details may be made. Any portion of the apparatus and/or methods described herein may be combined in any combination, except mutually exclusive combinations. The implementations described herein can include various combinations and/or sub-combinations of the functions, components and/or features of the different implementations described.

It will be understood that, in the foregoing description, when an element is referred to as being on, connected to, electrically connected to, coupled to, or electrically coupled to another element, it may be directly on, connected or coupled to the other element, or one or more intervening elements may be present. In contrast, when an element is referred to as being directly on, directly connected to or directly coupled to another element, there are no intervening elements present. Although the terms directly on, directly connected to, or directly coupled to may not be used throughout the detailed description, elements that are shown as being directly on, directly connected or directly coupled can be referred to as such. The claims of the application, if any, may be amended to recite exemplary relationships described in the specification or shown in the figures.

As used in this specification, a singular form may, unless definitely indicating a particular case in terms of the context, include a plural form. Spatially relative terms such as over, above, upper, under, beneath, below, lower, and so forth, are intended to encompass different orientations of the device in use or operation in addition to the orientation depicted in the figures. In some implementations, the relative terms above and below can, respectively, include vertically above and vertically below. In some implementations, the term adjacent can include laterally adjacent to or horizontally adjacent to.

Unless defined otherwise, all technical and scientific terms used herein have the same meaning as commonly understood by one of ordinary skill in the art. Methods and materials similar or equivalent to those described herein can be used in the practice or testing of the present disclosure. As used in the specification, and in the appended claims, the singular forms “a,” “an,” “the” include plural referents unless the context clearly dictates otherwise. The term “comprising,” and variations thereof as used herein is used synonymously with the term “including” and variations thereof and are open, non-limiting terms. The terms “optional” or “optionally” used herein mean that the subsequently described feature, event or circumstance may or may not occur, and that the description includes instances where said feature, event or circumstance occurs and instances where it does not. Ranges may be expressed herein as from “about” one particular value, and/or to “about” another particular value. When such a range is expressed, an aspect includes from the one particular value and/or to the other particular value. Similarly, when values are expressed as approximations, by use of the antecedent “about,” it will be understood that the particular value forms another aspect. It will be further understood that the endpoints of each of the ranges are significant both in relation to the other endpoint, and independently of the other endpoint.

Some implementations may be implemented using various semiconductor processing and/or packaging techniques. Some implementations may be implemented using various types of semiconductor processing techniques associated with semiconductor substrates including, but not limited to, for example, Silicon (Si), Gallium Arsenide (GaAs), Gallium Nitride (GaN), Silicon Carbide (SiC) and/or so forth.

What is claimed is:

1. A package, comprising:
an inorganic substrate;
an optical sensor die disposed on a first portion of a top surface of the inorganic substrate;
a first inter-metal dielectric layer disposed on a second portion of the top surface;
a second inter-metal dielectric layer disposed on a bottom surface of the inorganic substrate; and
at least one through-substrate via including conductive material to electrically connect the first inter-metal dielectric layer and the second inter-metal dielectric layer.

2. The package of claim 1, wherein the at least one through-substrate via includes copper.

3. The package of claim 1, further comprising; at least a wire bond electrically connecting a device contact pad on the optical sensor die to a conductive trace or pad in the first inter-metal dielectric layer.

4. The package of claim 1, further comprising: at least a solder ball coupled to a metallic pad in the second inter-metal dielectric layer.

5. The package of claim 1, wherein a cover is disposed above the optical sensor die disposed on the top surface of the inorganic substrate.

6. The package of claim 5, wherein the cover rests on a dam formed on the inorganic substrate along an edge of the optical sensor die or along an edge of the inorganic substrate.

7. The package of claim 6, wherein a top surface of the optical sensor die includes an optically active surface area, and the cover also rests on a dielectric layer disposed on the optically active surface area.

8. The package of claim 6, wherein the dam is formed of a black color material.

9. The package of claim 6, wherein a black color pattern is formed underneath an edge of the cover.

10. The package of claim 5, wherein the cover encloses an air cavity above an optically active surface area on a top surface of the optical sensor die.

11. The package of claim 10, wherein the cover includes a vent hole to the air cavity.

12. The package of claim 1, wherein the first inter-metal dielectric layer and the second inter-metal dielectric layer form portions of a signal redistribution layer for the optical sensor die in the package.

13. The package of claim 12, wherein the signal redistribution layer is a first signal redistribution layer, and the package further comprises a second signal redistribution layer for the optical sensor die in the package.

14. The package of claim 12, wherein the package further comprises multiple signal redistribution layers in the package.

15. A substrate, comprising:
a piece of glass;
a die attach pad disposed on a top surface of the piece of glass and configured to receive a semiconductor device die;
a first inter-metal dielectric layer disposed adjacent to the die attach pad on the top surface;
a second inter-metal dielectric layer disposed on a bottom surface of the piece of glass; and
at least one through-glass via extending from the top surface of the piece of glass to the bottom surface of the piece of glass.

16. The substrate of claim 15, wherein the first inter-metal dielectric layer includes conductive traces and pads configured to be wire bonded to the semiconductor device die received on the die attach pad.

17. The substrate of claim 15, wherein the second inter-metal dielectric layer includes at least one conductive pad configured to receive a solder ball making an external contact to the semiconductor device die received on the die attach pad.

18. The substrate of claim 15, wherein the at least one through-glass via is filled with conductive material electrically connecting the first inter-metal dielectric layer and the second inter-metal dielectric layer.

19. The substrate of claim 15, wherein the piece of glass is a borosilicate glass.

20. The substrate of claim 15, wherein the semiconductor device die is an optical sensor die.

21. A method, comprising:
disposing at least one inorganic substrate on a carrier, the at least one inorganic substrate including at least one through-substrate via extending from a first side to an opposite second side;
forming wire bonds between an optical sensor die and traces and pads in a first inter-metal dielectric layer disposed on a first side of the at least one inorganic substrate;
placing a cover over the optical sensor die;
applying encapsulating material on vertical sides of the cover, the optical sensor die, and the at least one inorganic substrate, the encapsulating material joining several individual inorganic substrate substrates disposed on the carrier together;
singulating through the encapsulating material to isolate individual inorganic substrates on the carrier;
transferring the individual inorganic substrates in upside down position onto a die holder; and
disposing solder bumps on a second inter-metal dielectric layer on the opposite second side of the individual inorganic substrates.

22. The method of claim 21, wherein placing the cover over the optical sensor die includes attaching the cover using an adhesive applied over the wire bonds.

23. The method of claim 22, wherein disposing solder bumps on the second inter-metal dielectric layer on the opposite second side of the individual inorganic substrates includes solder reflow processes to form a ball grid array for external electrical contacts or terminals of a package including the optical sensor die.
